(19) United States
(12) Patent Application Publication
(10) Pub. No.: US 2020/0126826 A1
(43) Pub. Date: Apr. 23, 2020

(54) LOAD LOCK BODY PORTIONS, LOAD LOCK APPARATUS, AND METHODS FOR MANUFACTURING THE SAME

(71) Applicant: Applied Materials, Inc., Santa Clara, CA (US)

(72) Inventors: Ram Dayal Malviya, Bangalore (IN); Travis Morey, Austin, TX (US); Theodossios V. Costuros, Manchaca, TX (US); Michael C. Kuchar, Georgetown, TX (US); Pandu Maddherla, Bangalore (IN); Richard Giljum, Brentwood, CA (US); Edward Ng, San Jose, CA (US)

(21) Appl. No.: 16/164,214

(22) Filed: Oct. 18, 2018

(51) Int. Cl. H01L 21/67; F28F 3/12

(52) U.S. Cl. CPC H01L 21/67201; H01L 21/67098; F28F 3/12

(57) ABSTRACT

A load lock apparatus may include a body portion including one or more surfaces. A first groove may extend into and along a first surface of the one or more surfaces. A first tube may be received in the first groove, wherein the first tube may be configured to transport a liquid (e.g., to thermally control the body portion). Other apparatus and methods of manufacturing load lock apparatus in accordance with these and other embodiments are disclosed.

### FIELD

The present disclosure relates to electronic device manufacturing, and more specifically to load lock apparatus and methods of manufacturing the same.

### BACKGROUND

Electronic device manufacturing systems may include multiple process chambers arranged around a mainframe housing having a transfer chamber and one or more load lock apparatus configured to pass substrates into and out of the transfer chamber. During some fabrication processes, the substrates may be heated to very high temperatures. When the hot substrates are passed through the load lock apparatus, they heat the load lock apparatus, which makes it difficult to cool substrates while they are in the load lock apparatus.

### SUMMARY

In a first aspect, a body portion of a load lock apparatus is provided. The body portion includes one or more surfaces; a first groove extending into and along a first surface of the one or more surfaces; and a first tube received in the first groove, the first tube configured to transport a liquid.

In another aspect, a load lock apparatus is provided. The load lock apparatus includes a first body portion including a first surface and a second surface; a second body portion including a third surface at least partially in contact with the first surface; a first groove extending into and along the first surface; a second groove extending into and along the second surface; a first tube received in the first groove, the first tube configured to transport a liquid; and a second tube received in the second groove, the second tube configured to transport a liquid.

In another aspect, a method of manufacturing a load lock apparatus is provided. The method includes providing a first body portion of the load lock apparatus, the first body portion including a surface; forming a groove into and along the surface; and inserting a tube into the groove, wherein the tube is configured to transport a liquid.

Other features and aspects of the present disclosure will become more fully apparent from the following detailed description, the appended claims, and the accompanying drawings.

### BRIEF DESCRIPTION OF THE DRAWINGS

The drawings, described below, are for illustrative purposes and are not necessarily drawn to scale. The drawings are not intended to limit the scope of the disclosure in any way.

FIG. 1 illustrates a schematic, top view of an electronic device processing system including two load lock apparatus according to one or more embodiments.

FIG. 2A illustrates a top, isometric view of a load lock apparatus including three body portions according to one or more embodiments.

FIG. 2B illustrates a top, isometric view of a load lock apparatus including three body portions according to one or more embodiments.

FIG. 3A illustrates a top, isometric view of a main body portion of a load lock apparatus according to one or more embodiments.

FIG. 3B illustrates a partial cross-sectional view of a first body portion of a load lock apparatus including a groove formed into a surface thereof according to one or more embodiments.

FIG. 3C illustrates a partial cross-sectional view of a first body portion of a load lock apparatus including a groove formed into a surface thereof and a tube located in the groove according to one or more embodiments.

FIG. 4 illustrates a bottom, plan view of a first body portion of a load lock apparatus according to one or more embodiments.

FIG. 5 illustrates a bottom, plan view of a load lock apparatus according to one or more embodiments.

FIG. 6 schematically illustrates a liquid flow controller coupled to a load lock apparatus according to one or more embodiments.

FIG. 7 illustrates a flowchart showing a method for manufacturing a load lock apparatus according to one or more embodiments.

### DETAILED DESCRIPTION

Reference will now be made in detail to the example embodiments of this disclosure, which are illustrated in the accompanying drawings. Wherever possible, the same reference numbers will be used throughout the drawings to refer to the same or like parts throughout the several views. Features of the various embodiments described herein may be combined with each other, unless specifically noted otherwise.

Electronic device manufacturing may involve exposing substrates to different environmental conditions during a plurality of processes. These environmental conditions may include exposing substrates to various chemicals and to very high temperatures. In between different processes, the substrates may be maintained in controlled environments to prevent ambient air from adversely affecting the substrates. For example, exposure to water vapor or oxygen may adversely affect some substrates.

The electronic device manufacturing may be performed in an electronic device processing apparatus. An electronic device processing apparatus may include a transfer chamber that distributes substrates to and receives substrates from one more process chambers. One or more load lock apparatus may be coupled between the transfer chamber and an electronic front end module (EFEM). The substrates are transferred between the transfer chamber and the EFEM via the load lock apparatus.

The controlled environments that the substrates are exposed to may be maintained by passing the substrates through load lock apparatus as they transfer between the EFEM and the transfer chamber. A load lock apparatus may have a first opening adjacent an EFEM and a second opening adjacent a transfer chamber. During transfer of a substrate from the transfer chamber to the EFEM, the first opening may be sealed and the second opening may be unsealed to receive the substrate into the load lock apparatus. When the substrate is in the load lock apparatus, the both openings may be sealed. Environmental conditions within the load lock apparatus may then be set. The first opening may then be unsealed and the substrate may be removed from the load lock apparatus and transported into the EFEM.

The substrates entering the load lock apparatus from the transfer chamber may be extremely hot and may heat the body of the load lock apparatus. Some load lock apparatus may heat substrates prior to the substrates being transferred to the transfer chamber. In both load lock apparatus embodiments, bodies of the load lock apparatus may become hot and may cause injury to operators who contact hot load lock apparatus. Some load lock apparatus include cooling devices to cool the substrates. However, the load lock bodies may have been heated as described above, which makes cooling the substrates difficult.

Load lock apparatus disclosed herein may include cooled load locks with one or more body portions including at least one surface. At least one groove extends into and along at least one surface. Tubes configured to transport a liquid (e.g., a cooling liquid) may be located in the grooves. Heat from the body portions can be transferred to the liquid via the tubes, which operates to cool the body portions. In some embodiments, the tubes include copper or other thermally-conductive materials that are good heat conductors. The tubes may be swaged into the grooves to provide a tight fit and enhanced contact of each tube within the respective body portions, which improves the heat transfer from the body portions to the tubes and the liquid transported therein.

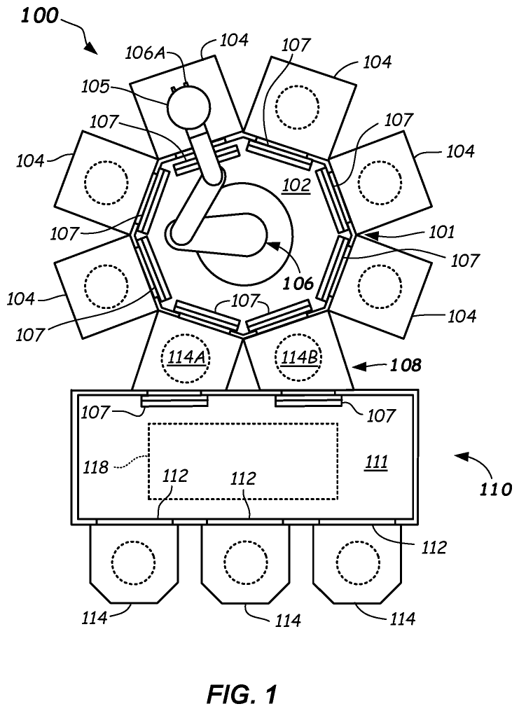

Further details of example embodiments of body portions for load lock apparatus (e.g., cooled load locks), thermally-controlled load lock apparatus, and methods for manufacturing the same are described with reference to FIGS. 1-7 herein.

FIG. 1 illustrates a top view of a schematic diagram of an electronic device processing apparatus. The electronic device processing apparatus may be adapted to process substrates (e.g., 300 mm or 450 mm silicon-containing wafers, silicon plates, or the like) by imparting one or more processes thereto, such as degassing, cleaning or pre-cleaning, deposition such as chemical vapor deposition (CVD), physical vapor deposition (PVD), or atomic layer deposition, coating, oxidation, nitration, etching, polishing, lithography, or the like.

The depicted electronic device processing apparatus 100 may include a mainframe housing 101 including a transfer chamber 102 formed therein. The transfer chamber 102 may be formed by a lid (removed for illustration purposes), a bottom, and side walls, and may be maintained at a vacuum in some embodiments, for example. The mainframe housing 101 may include any suitable shape, such as square, rectangular, pentagon, hexagon, heptagon, octagon (as shown), nonagon, or other geometric shapes. In the depicted embodiment, a robot 106, such as a multi-arm robot may be received at least partially inside of the transfer chamber 102 and may be adapted to be operable therein to service various chambers (e.g., one or more process chambers 104 and/or one or more load lock apparatus 108) arranged around the transfer chamber 102. “Service” as used herein means to place or pick a substrate 105 into or out of a chamber (e.g., a process chamber 104 and/or a load lock apparatus 108) with an end effector 106A of the robot 106. The transfer chamber 102 depicted in FIG. 1 is coupled to six process chambers 104 and two load lock apparatus 108. However, other numbers of process chambers 104 and load lock apparatus 108 may be used.

The robot 106 may be adapted to pick and place substrates 105 (sometimes referred to as “wafers” or “semiconductor wafers”) mounted on the end effector 106A (sometimes referred to as a “blade”) of the robot 106 to or from a destination through one or more slit valve assemblies 107. In the depicted embodiment of FIG. 1, the robot 106 may be any suitable multi-arm robot that has sufficient mobility to transfer substrates 105 between the various process chambers 104 and/or the load lock apparatus 108.

The load lock apparatus 108 may be adapted to interface with an interface chamber 111 of an electronic front end module (EFEM) 110. The EFEM 110 may receive substrates 105 from substrate carriers 114, such as front opening unified pods (FOUPs) docked at load ports 112 on a front wall of the EFEM 110. A load/unload robot 118 (shown dotted) may be used to transfer substrates 105 between the substrate carriers 114 and the load lock apparatus 108. Slit valve assemblies 107 may be provided at some or all of the openings into the process chambers 104 and also at some or all of the openings of the load lock apparatus 108.

Substrates may be received into the transfer chamber 102 from the EFEM 110 and may also exit the transfer chamber 102, to the EFEM 110, through the load lock apparatus 108 that are coupled to a surface (e.g., a rear wall) of the EFEM 110. The load lock apparatus 108 may include one or more load lock chambers (e.g., load lock chambers 114A, 114B, for example). Load lock chambers 114A, 114B that are included in the load lock apparatus 108 may be single wafer load lock (SWLL) chambers, multi-wafer chambers, or combinations thereof, for example.

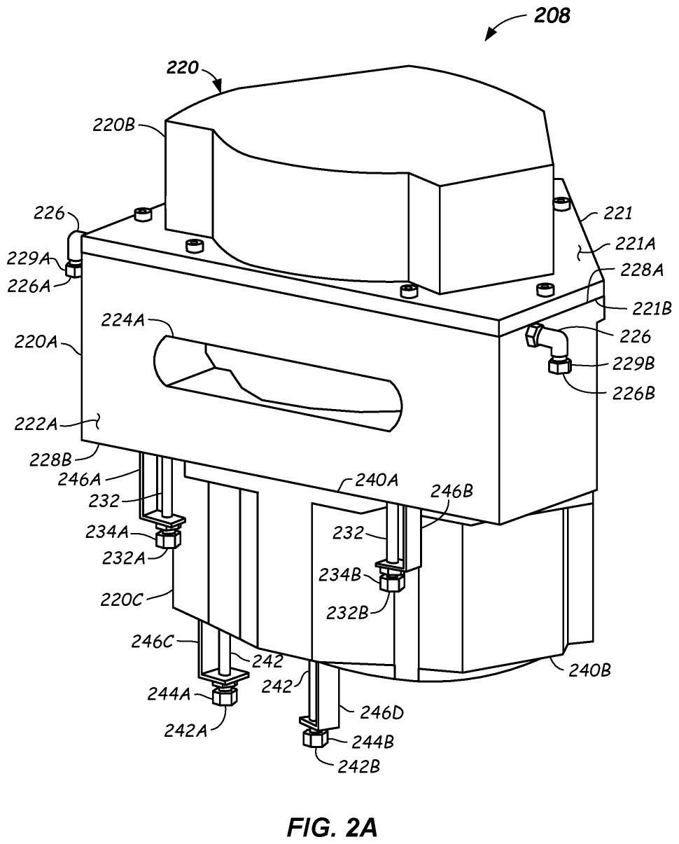

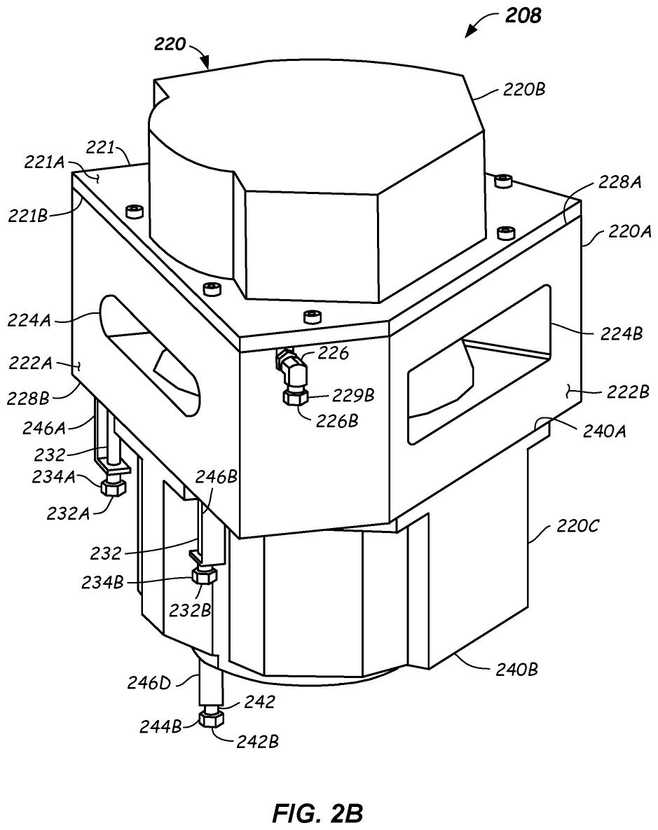

Reference is now made to FIGS. 2A and 2B, which illustrate top, isometric views of a load lock apparatus 208 including cooling. The load lock apparatus 208 may be substantially similar to the load lock apparatus 108 of FIG. 1. In some embodiments, the load lock apparatus 208 may include one or more body portions 220, which may be referred to as a first body portion 220A, a second body portion 220B, and a third body portion 220C. The body portions 220 may be made of aluminum 6061-T6 material or other suitable thermally conductive metals, for example. The first body portion 220A may be referred to as a main body portion, the second body portion 220B may be referred to as an upper lid, and the third body portion 220C may be referred to as a lower bell jar. The body portions 220 may be secured to each other by the use of fasteners (not shown) and seals so as to form airtight seals between the interfaces of the individual body portions 220. The second body portion 220B may include a plate 221 including a first surface 221A and a second surface 221B.

The first body portion 220A may include a first exterior interface 222A and a second exterior interface 222B. The first exterior interface 222A and the second exterior interface 222B may be configured to contact an exterior wall of either the mainframe housing 101 (FIG. 1) or the EFEM 110 (FIG. 1). Slit valve assemblies 107 (FIG. 1) may be coupled to at least a portion of both the first exterior interface 222A and the second exterior interface 222B.

The first exterior interface 222A may include a first opening 224A and the second exterior interface 222B may include a second opening 224B. Both the first opening 224A and the second opening 224B may be configured to pass substrates 105 (FIG. 1) into and out of the first body portion 220A. As described above, the substrates 105 may be hot and may heat the body portions 220 of the load lock apparatus 208 in some embodiments. In some embodiments, the load lock apparatus 208 may include devices (not shown) that cool and/or heat the substrates 105. Cooling of the substrates 105 may be inefficient when the body portions 220 are too hot.

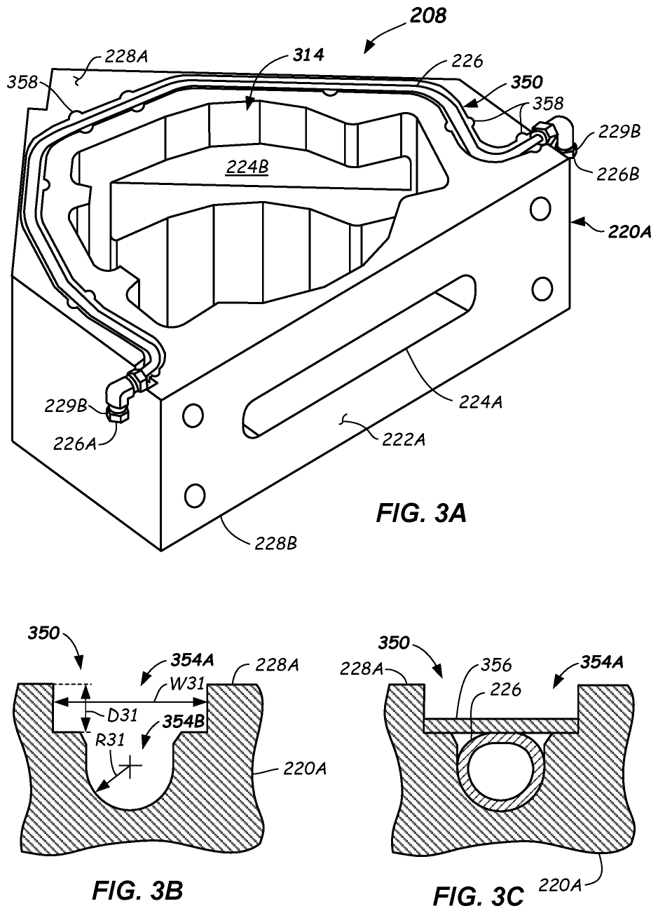

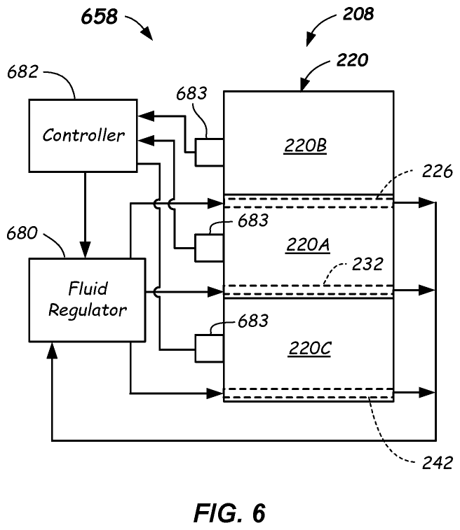

The load lock apparatus 208 may include one or more tubes (e.g., cooling lines) received in grooves (not shown in FIGS. 2A and 2B) formed into and extending along surfaces of the body portions 220. In the embodiment shown in FIGS. 2A and 2B, the load lock apparatus 208 may include a first tube 226 received in a groove (e.g., first groove 350, FIG. 3) extending into and along a first surface 228A of the first body portion 220A. The first tube 226 may include a first opening 226A and a second opening 226B, wherein a liquid (not shown) may be transported (flow) between the first opening 226A and the second opening 226B. The first opening 226A may have a first coupler 229A attached thereto and the second opening 226B may have a second coupler 229B attached thereto. The first coupler 229A and the second coupler 229B may couple the first tube 226 to a liquid regulator 680 (FIG. 6) or other liquid-transporting device and can interconnect to a liquid source.

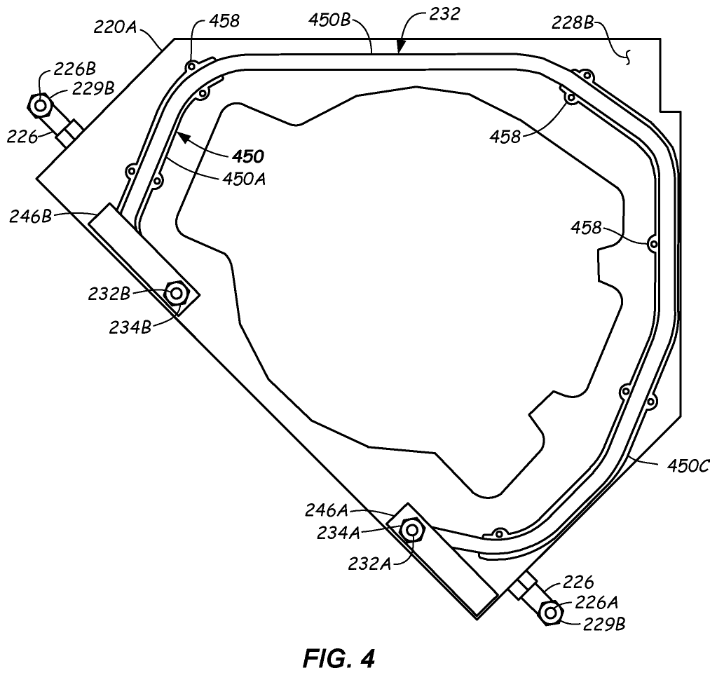

A second tube 232 may be received in a groove (e.g., second groove 450, FIG. 4) formed into and extending along a second surface 228B of the first body portion 220A. In some embodiments, the first surface 228A may be parallel to the second surface 228B. The second tube 232 may include a first opening 232A and a second opening 232B, wherein a liquid (not shown) may be transported between the first opening 232A and the second opening 232B. The first opening 232A may have a first coupler 234A attached thereto and the second opening 232B may have a second coupler 234B attached thereto. The first coupler 234A and the second coupler 234B may couple the second tube 232 to the liquid regulator 680 (FIG. 6) or other liquid-transporting device and can interconnect to a liquid source.

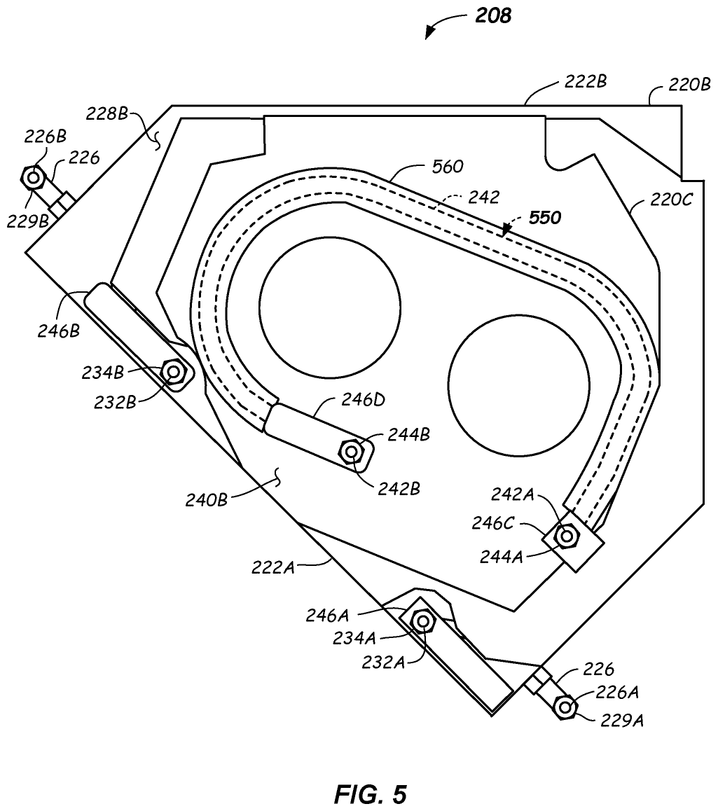

The third body portion 220C may include a first surface 240A and a second surface 240B. The first surface 240A may abut at least a portion of the second surface 228B of the first body portion 220A and the second surface 240B may be a lower surface of the load lock apparatus 208. A third tube 242 may be received in a groove (e.g., third groove 550, FIG. 5) formed into an extending along the second surface 240B. The third tube 242 may include a first opening 242A and a second opening 242B, wherein a liquid (not shown) may be transported between the first opening 242A and the second opening 242B. The first opening 242A may have a first coupler 244A attached thereto and the second opening 242B may have a second coupler 244B attached thereto. The first coupler 244A and the second coupler 244B may couple the third tube 242 to the liquid regulator 680 (FIG. 6) or other liquid-transporting device and can interconnect to a liquid source.

A first bracket 246A may support the first opening 232A and the first coupler 234A of the second tube 232 from the second surface 228B of the first body portion 220A. A second bracket 246B may support the second opening 232B and the second coupler 234B from the second surface 228B of the first body portion 220A. A third bracket 246C may support the first opening 242A and the first coupler 244A of the third tube 242 from the second surface 240B of the third body portion 220C. A fourth bracket 246D may support the second opening 242B and the second coupler 244B of the third tube 242 from the second surface 240B of the third body portion 220C.

Reference is now made to FIG. 3A, which illustrates a top, isometric view of the first body portion 220A. The first body portion 220A may include a chamber 314 or a portion of the chamber 314 that may be sized and configured to receive substrates (e.g., substrates 105, FIG. 1) via the first opening 224A and the second opening 224B. The first surface 228A may include a first groove 350 formed therein and extending into and along the first surface 228A. In some embodiments, the first groove 350 may at least partially encircle the chamber 314. The first groove 350 may be sized and configured to receive the first tube 226 therein.

Additional reference is made to FIG. 3B, which illustrates a partial cross-sectional view of the first body portion 220A including the first groove 350. Additional reference is also made to FIG. 3C, which illustrates a partial cross-sectional view of the first body portion 220A including the first groove 350 with the first tube 226 received therein. The second tube 232 (FIG. 2A), the third tube 242 (FIG. 2A), the second groove 450 (FIG. 4), and the third groove 550 (FIG. 5) may be identical or substantially similar to the first groove 350 and the first tube 226.

The first groove 350 depicted in FIGS. 3B and 3C may include an upper portion 354A and a lower portion 354B. The upper portion 354A may have a depth D31 and a width W31. The lower portion 354B may include a radius R31 that may be slightly larger than the outer radius of the first tube 226. The first tube 226 may be pressed or swaged into the lower portion 354B of the first groove 350. The first tube 226 may be made of a soft, high thermal conductivity metal, such as copper, that may deform slightly when pressed or swaged into the first groove 350. The deforming and/or swaging of the first tube 226 into the first groove 350 forms a tight fit (line or compressed fit) between the first body portion 220A and the first tube 226, which can appreciably enhance conductive heat transfer between the first body portion 220A and the first tube 226. The swaging operation dramatically improves the respective surface area of the tube first 226 in direct intimate thermal contact with the walls of the lower portion 354B of the groove 350. The materials of the first tube 226 along the length thereof may be a good thermal conductor so as to conduct heat from the first body portion 220A and to a liquid transported via the first tube 226.

In some embodiments, a plate 356, such as a thermally-conductive metal plate, may be placed in the upper portion 354A of the first groove 350 and may press the first tube 226 into the lower portion 354B. For example, the plate 356 may contact or even deform the top or other portions of the first tube 226 as shown in FIG. 3C, which enhances the tight fit of the first tube in the first groove 350. Moreover, it can further enhance the thermal contact with the first tube, by contact with the portion of the first tube 226 not in contact with the wall, and thus providing a thermal bridge to the first body portion 220A. In some embodiments the first groove 350 may include a plurality of pockets 358 (a few labelled) including threaded bores that may receive fasteners (e.g., screws) that secure the plate 356 into the upper portion 354A of the first groove 350. As should be recognized, the swaging of the tube may be accomplished by a tool that contacts the first tube along all or a portion of its length. A suitable deforming force can be applied to the tool to swage the first tube 226 into the lower portion 354B of the groove 350.

Some embodiments of the first groove 350 do not include the upper portion 354A. Rather, the first groove 350 may include solely the lower portion 354B. In such embodiments, the top of the first tube 226 may be proximate a plane defined by the first surface 228A. A plate or plurality of plates (e.g., plate 560, FIG. 5), such as flat metal strips may be placed over the first groove 350 and may contact and/or deform the first tube 226 in a similar manner as the plate 356. In some embodiments, the first groove 350 may be at least partially covered by the second body portion 220B. For example, as shown in FIGS. 2A and 2B, the second surface 221B of the plate 221 may contact at least a portion of the first tube 226 located in the first groove 350.

Reference is now made to FIG. 4, which illustrates a top plan view of the second surface 228B of the first body portion 220A on aside opposite from the first surface 228A. A second groove 450 may extend into and along the second surface 228B and may receive the second tube 232. The second groove 450 may be sized and configured to receive the second tube 232 in the same manner as the first groove 350 (FIGS. 3B and 3C) is sized and configured to receive the first tube 226. The second groove 450 may include three portions, a first portion 450A, a second portion 450B, and a third portion 450C. The first portion 450A and the third portion 450C may include an upper portion or other portion that is wider than the second portion 450B. A plate may be received in or cover the upper portion. For example, the first portion 450A and the third portion 450C may be configured to receive a plate or be covered by a plate to secure the second tube 232 in the second groove 450. In some embodiments, the plate may be substantially similar or identical to the plate 356 (FIG. 3C). The first portion 450A and the third portion 450C may include pockets 458 to receive fasteners (e.g., screws) that secure the plate into the second groove 450.

The second portion 450B of the second groove 450 may be narrow and may be configured to have a surface of the third body portion 220C press against the second tube 232 located therein. For example, at least one portion of the first surface 240A (FIGS. 2A and 2B) may abut the second portion 450B of the second groove 450 and may press the second tube 232 into the second groove 450. As shown in FIG. 4, portions of the first bracket 246A and the second bracket 246B may cover portions of the second groove 450 and may press the second tube 232 into the second groove 450.

Reference is now made to FIG. 5, which illustrates a bottom, plan view of the load lock apparatus 208. The view of FIG. 5 includes the second surface 240B of the third body portion 220C and may include a third groove 550 that may extend into an along the second surface 240B. The third tube 242 may be received into the third groove 550. For example, the third tube 242 may be swaged into the third groove 550. The second surface 240B may be the bottom of the load lock apparatus 208, so it may not have another body portion abutting it, which would otherwise maintain the third tube 242 in the third groove 550. A plate 560 may be positioned over at least a portion of the third groove 550 and may cover at least a portion of the third tube 242. Accordingly, the plate 560 may maintain the third tube 242 in the third groove 550.

The tubes 226, 232, 242 may be configured to transport a liquid, which may cool the load lock apparatus 208 in some embodiments. For example, ordinary water (e.g., tap water) or water from a manufacturing facility where the load lock apparatus 208 is located may be pumped through the tubes 226, 232, 242 to cool the load lock apparatus 208. Use of water provides cost effective cooling.

Reference is now made to FIG. 6, which schematically illustrates an embodiment of a liquid flow control assembly 658 that may control liquid flow through the tubes 226, 232, 242. The liquid flow control assembly 658 may include a controller 682, which may be a digital computer including a processor and memory, that may monitor the temperature of the load lock apparatus 208, or portions thereof, and generate control signals to control liquid flow through the tubes 226, 232, 242 in response to the monitoring. For example, the controller 682 may generate control signals that are transmitted to the liquid regulator 680. The control signals may cause the liquid regulator 680, which may comprise a series of suitable active valves or proportioning valves, to direct liquid flow through specific ones of the tubes 226, 232, 242 in response to the control signals. The temperature monitoring may be provided by one or more temperature sensors 683 coupled to one or more of the body portions 220A-220C and that provide temperature feedback to the controller 682. The control signals can be generated responsive the temperature feedback signals from the one or more sensors 683 to control the one or more body portions 220A-220C to one or more desired temperature set points. In some embodiments, the liquid regulator 680 may facilitate cooling (and or heating) of the liquid. Some embodiments of the load lock apparatus 208 (FIG. 2A) may not be coupled to a controller 682, but may be passive. For example, these passive embodiments of the load lock apparatus 208 may continuously pump chilled water through the tubes 226, 232, 242 and thus cool one or more of the body portions 220A-220C.

The load lock apparatus 208 may include benefits relative to traditional load lock apparatus. For example, some traditional load lock apparatus include gun-drilled holes to transport a cooling liquid. The grooves disclosed herein are easier and less expensive to manufacture than the traditional gun-drilled holes, and have no cross-plugging. The traditional load lock apparatus that include gun-drilled holes expose the body portions directly to the cooling liquid, so non-corrosive liquids are used for cooling, which are more expensive than water. For example, some traditional load lock apparatus use ethylene glycol mixed with di-ionized water as a cooling liquid. The load lock apparatus 208 disclosed herein includes the tubes 226, 232, 242 for transporting the cooling liquid, so the body portions are not exposed to the cooling liquid. Accordingly water or other cost-effective cooling liquids may be used with the load lock apparatus 208. In addition, the traditional load lock apparatus using cooling liquids such as ethylene glycol mixed with di-ionized water include heat exchangers, which can further increase the cost of the load lock apparatus. The use of chilling water passing through the tubes 226, 232, 242 does not necessarily require a heat exchanger, such as in the passive version wherein the waste water would simply be disposed of.

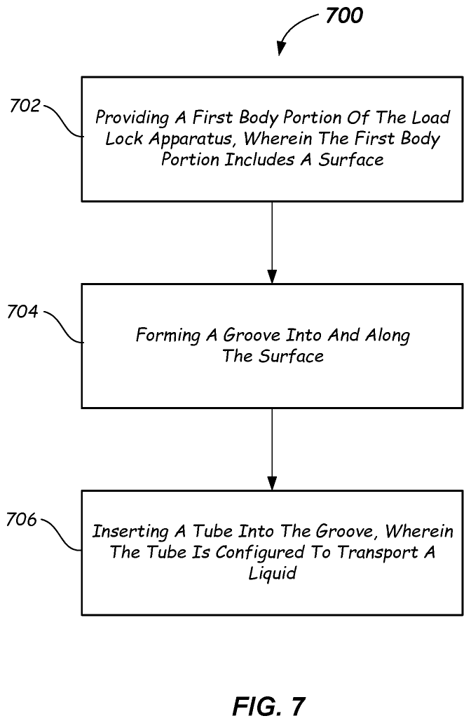

In another aspect, a method of manufacturing a load lock apparatus (e.g., load lock apparatus 208) is disclosed and illustrated by the flowchart 700 of FIG. 7. The load lock apparatus 208 may be a cooled load lock. The method may include, in 702, providing a first body portion (e.g., first body portion 220A) of the cooled load lock apparatus, wherein the first body portion includes a surface (e.g., first surface 228A). The method may include, in 704, forming a groove (e.g., first groove 350) into and along the surface. The method may include, in 706, inserting a tube (e.g., first tube 226) into the groove, wherein the tube is configured to transport a liquid. The tube may be swaged into the groove thus increasing the thermal contact with the surface of the groove.

The foregoing description discloses example embodiments of the disclosure. Modifications of the above-disclosed apparatus, systems, and methods which fall within the scope of the disclosure will be readily apparent to those of ordinary skill in the art. Accordingly, while the present disclosure has been disclosed in connection with example embodiments, it should be understood that other embodiments may fall within the scope of the disclosure, as defined by the claims.

What is claimed is:

1. A body portion of a load lock apparatus, comprising:
one or more surfaces;
a first groove extending into and along a first surface of the one or more surfaces; and
a first tube received in the first groove, the first tube configured to transport a liquid.

2. The body portion of claim 1, wherein the first tube is swaged into the first groove.

3. The body portion of claim 1, wherein the first tube comprises copper.

4. The body portion of claim 1, wherein the first surface is configured to at least partially contact a second surface of a second body portion, and wherein the second surface at least partially covers the first groove.

5. The body portion of claim 1, wherein the first groove includes a first portion and a second portion, the first portion configured to receive the first tube, and the second portion configured to receive a plate that at least partially covers the first tube.

6. The body portion of claim 1, further comprising a plate located adjacent the first surface and at least partially covering the first tube.

7. The body portion of claim 1, further comprising a liquid regulator coupled to the first tube, the liquid regulator configured to regulate liquid flow through the first tube.

8. The body portion of claim 1, further comprising:
a second surface located on the body portion;
a second groove extending into and along the second surface; and
a second tube received in the second groove, the second tube configured to transport a liquid.

9. The body portion of claim 8, further comprising a liquid regulator coupled to the first tube and the second tube, the liquid regulator configured to regulate liquid flow through the first tube and the second tube.

10. The body portion of claim 8, wherein the first surface is parallel to the second surface.

11. A load lock apparatus, comprising:
a first body portion including a first surface and a second surface;
a second body portion including a third surface at least partially in contact with the first surface;
a first groove extending into and along the first surface;
a second groove extending into and along the second surface;
a first tube received in the first groove, the first tube configured to transport a liquid; and
a second tube received in the second groove, the second tube configured to transport a liquid.

12. The load lock apparatus of claim 11, wherein the first tube is swaged into the first groove.

13. The load lock apparatus of claim 11, wherein the third surface at least partially covers the first groove.

14. The load lock apparatus of claim 11, further comprising at least one plate at least partially covering the first tube.

15. The load lock apparatus of claim 11, wherein the first groove includes a first portion and a second portion, the first portion configured to receive the first tube, and the second portion configured to receive a plate that at least partially covers the first tube.

16. The load lock apparatus of claim 11, further comprising a liquid regulator coupled to the first tube and the second tube, the liquid regulator configured to regulate liquid flow through the first tube and the second tube.

17. The load lock apparatus of claim 11, further comprising a third body portion attached to the second surface of the first body portion.

18. A method of manufacturing a load lock apparatus, comprising:
providing a first body portion of the load lock apparatus, the first body portion including a surface;
forming a groove into and along the surface; and
inserting a tube into the groove, wherein the tube is configured to transport a liquid.

19. The method of claim 18, wherein inserting a tube into the groove comprises swaging the tube into the groove.

20. The method of claim 18, further comprising attaching a second body portion of the load lock apparatus to the surface, wherein the second body portion at least partially covers the groove.
